(19) United States
(12) Patent Application Publication
(10) Pub. No.: US 2015/0179243 A1
(43) Pub. Date: Jun. 25, 2015

(54) WORD LINE DRIVING CIRCUIT

(71) Applicant: SK hynix Inc., Gyeonggi-do (KR)

(72) Inventor: Sung-Soo CHI, Gyeonggi-do (KR)

(21) Appl. No.: 14/299,928

(22) Filed: Jun. 9, 2014

(30) Foreign Application Priority Data
Dec. 19, 2013 (KR) 10-2013-0159281

(51) Int. Cl. G11C 8/08

(52) U.S. Cl. CPC G11C 8/08

(57) ABSTRACT

The word line driving circuit includes a plurality of first pull-down transistors connected in series and suitable for pull-down driving a control node in response to a plurality of address information signals, a driving signal output unit suitable for activating a word line driving signal when the control node is activated and deactivating the word line driving signal when a word line off signal is activated, a first pull-up transistor suitable for pull-up driving the control node when the word line driving signal is deactivated, and a clamping unit suitable for limiting the amount of current flowing to the first pull-up transistor.

### CROSS-REFERENCE TO RELATED APPLICATIONS

The present application claims priority of Korean Patent Application No. 10-2013-0159281, filed on Dec. 19, 2013, which incorporated herein by reference in its entirety.

### BACKGROUND

1. Field

Exemplary embodiments of the present invention relate to a semiconductor memory device, and more particularly, to a word line driving circuit.

2. Description of the Related Art

As is well known, word lines control the gates of a memory cells in semiconductor memory devices. The structure of word lines and bit lines in a semiconductor memory cell array will be described below.

FIG. 1 illustrates the word line, bit line, and memory cell structures in the cell array of a typical semiconductor memory device.

Referring to FIG. 1, the typical cell array includes a plurality of word lines WL0 to WLX and a plurality of pairs of bit lines BL0 and BLb0 to BLN and BLbN. The cell array has (X+1)*(N+1) numbers of memory cells corresponding to the (X+1) numbers of the word lines WL0 to WLX multiplied by the (N+1) number of the bit lines pairs BL0 and BLb0 to BLN and BLbN. Each of the memory cells includes a capacitor for storing data and transistors for controlling contact between the capacitor and the bit line. Bit line sense amplifiers 110_0 to 110_N amplify data of the bit lines pairs BL0 and BLb0 to BLN and BLbN.

When one of the word lines WL0 to WLX selected by a row address is activated during an active operation, data of the memory cells corresponding to the activated word line is transmitted to the bit lines pairs BL0 and BLb0 to BLN and BLbN. This is referred to as a charge sharing. The data transmitted to the bit lines pairs BL0 and BLb0 to BLN and BLbN is sense-amplified by the bit line sense amplifiers 110_0 to 110_N. When a column is selected based on its address during a read operation, data of the bit line sense amplifier corresponding to the selected column is outputted to the exterior of the semiconductor memory device. Number of the selected column can be one or more.

A circuit activating a selected word line of a plurality of word lines WL0 to WLX based on an address is referred to as a word line driving circuit. The word line driving circuit is essential and occupies a large portion of a semiconductor memory device. It is important to optimize the design of the word line driving circuit.

### SUMMARY

Exemplary embodiments of the present invention are directed to a word line driving circuit for driving a plurality of word lines without failure.

In accordance with an embodiment of the present invention, a word line driving circuit may include a plurality of first pull-down transistors connected in series and suitable for pull-down driving a control node in response to a plurality of address information signals, a driving signal output unit suitable for activating a word line driving signal when the control node activates and deactivates the word line driving signal when a word line off signal is activated, a first pull-up transistor suitable for pull-up driving the control node when the word line driving signal is deactivated, and a clamping unit suitable for limiting the amount of current flowing to the first pull-up transistor.

In accordance with another embodiment of the present invention, a word line driving circuit may include a plurality of main word line control units suitable for generating a plurality of main word line driving signals in response to a plurality of first address information signals, a plurality of local word line control units suitable for generating a plurality of local word line driving signals in response to a plurality of second address information signals, and a plurality of word line drivers suitable for driving a plurality of word lines according to the multiple main word line driving signals and local word line driving signals. Each of the multiple main word line control units may include a plurality of first pull-down transistors, a driving signal output unit, a first pull-up transistor, and a clamping unit. The plurality of first pull-down transistors may be connected in series, and may pull-down drive a first control node in response to the plurality of first address information signals. The driving signal output unit may activate a main word line driving signal when the first control node is activated, and deactivate the main word line driving signal when a word line off signal is activated. The first pull-up transistor may pull up drive the first control node when the main word line driving signal is deactivated. The clamping unit may limit the amount of current flowing to the first pull-up transistor.

### BRIEF DESCRIPTION OF THE DRAWINGS

FIG. 1 is a diagram illustrating the structure of a word line, bit line, and a memory cell in a typical semiconductor memory device cell array.

FIG. 2 is a block diagram illustrating a word line driving circuit in accordance with an embodiment of the present invention.

FIG. 3 is a block diagram illustrating an example of a main word line control unit shown in FIG. 2.

FIG. 4 is a block diagram illustrating an example of a local word line control unit shown in FIG. 2.

FIG. 5 is a block diagram illustrating an example of a word line driver shown in FIG. 2.

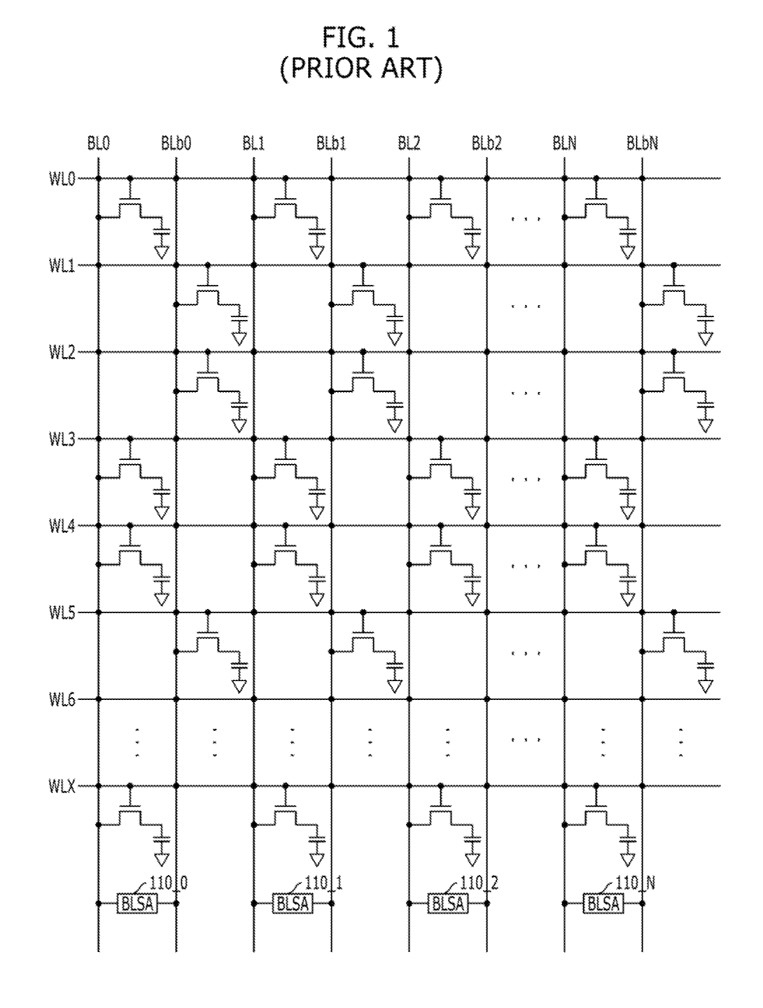

### DETAILED DESCRIPTION

Exemplary embodiments of the present invention will be described below in more detail with reference to the accompanying drawings. These embodiments are provided so this disclosure will be thorough and complete, and will fully convey the scope of the present invention to those skilled in the art. In describing the present invention, widely-known structures and components irrelevant to its substance will be omitted. Additionally, like reference numerals refer to like parts in the various figures and embodiments.

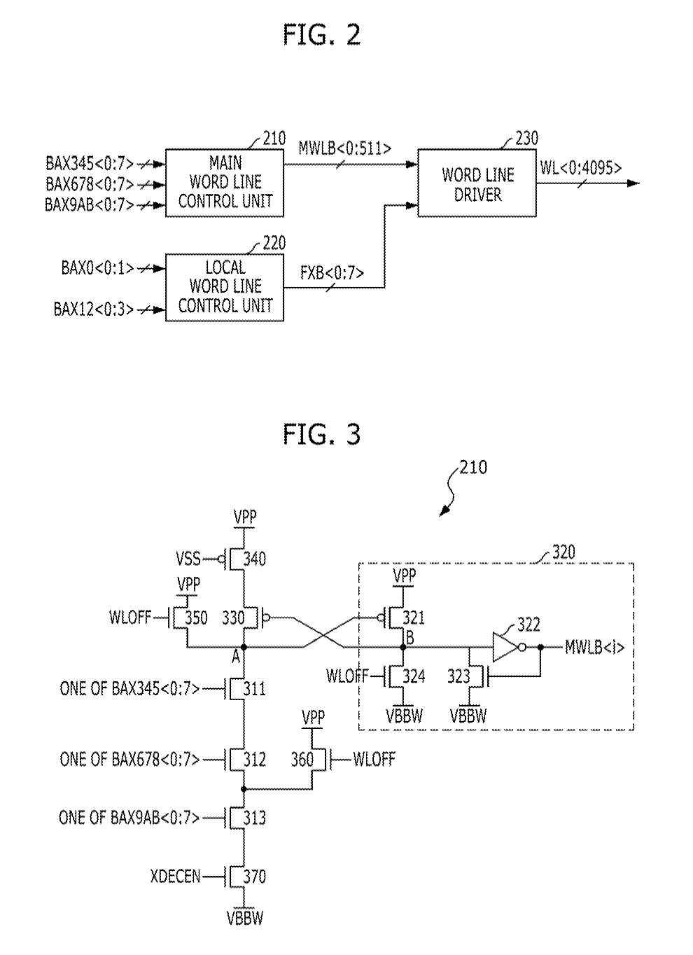

FIG. 2 is a block diagram illustrating a word line driving circuit in accordance with an embodiment of the present invention.

Referring to FIG. 2, the word line driving circuit may include a plurality of main word line control units 210, a plurality of local word line control units 220 and a plurality of word line drivers 230.

The multiple main word line control units 210 may generate a plurality of main word line driving signals MWLB<0:511>. Each of the multiple main word line control units 210 may generate each of the main word line driving signals MWLB<0:511> and thus the number of main word line control units 210 provided may equal the number of the main word line driving signals MWLB<0:511>. For example, if the number of main word line driving signals MWLB<0:511> is 512, the number of the main word line control units 210 may be 512 as well. The main word line control units 210 may generate the main word line driving signals MWLB<0:511> in response to first address information signals BAX345<0:7>, BAX678<0:7> and BAX9AB<0:7>. One of the main word line driving signals MWLB<0:511> selected according to the first address information signals BAX345<0:7>, BAX678<0:7> and BAX9AB<0:7> may be activated.

The multiple local word line control units 220 may generate a plurality of local word line driving signals FXB<0:7>. Each of the local word line control units 220 may generate each of the local word line driving signals FXB<0:7>, and thus the multiple local word line control units 210 may equal the number of the local word line driving signals FXB<0:7>. For example, if the number of the local word line driving signals FXB<0:7> is 8, the number of the local word line control units 220 may be 8 as well. The local word line control units 220 may generate the local word line driving signals FXB<0:7>, respectively, in response to second address information signals BAX0<0:1> and BAX12<0:3>. One of the local word line driving signals FXB<0:7> selected according to the second address information signals BAX0<0:1> and BAX12<0:3> may be activated.

The multiple word line drivers 230 may drive a plurality of word lines WL<0:4095> in response to the plurality of main word line driving signals MWLB<0:511> and the plurality of local word line driving signals FXB<0:7>. Each of the word line drivers 230 may drive each of the word lines WL<0:4095> and the number of multiple word line drivers 230 may equal the number of the word lines WL<0:4095>. Each of the word line drivers 230 may receive a different combination of the word line driving signals MWLB<0:511> and local word line driving signals FXB<0:7>. The 512 main word line driving signals MWLB<0:511> and the 8 local word line driving signals FXB<0:7> leads to 4096 combinations, which may be inputted to 4096 word line drivers 230.

Detailed structure and operation of the main word line control units 210, the local word line control units 220 and the word line drivers 230 will be described below with reference to the accompanying drawings.

FIG. 3 is a block diagram illustrating an example of the main word line control unit 210 shown in FIG. 2. As described above, the main word line control units 210 may equal the number of the main word line driving signals MWLB<0:511>. One of the main word line control units 210 is described in detail with reference to the accompanying drawing FIG. 3.

Referring to FIG. 3, the main word line control unit 210 may include a plurality of first pull-down transistors 311 to 313, a driving signal output unit 320, a first pull-up transistor 330, a clamping unit 340, a third pull-up transistor 350, a fourth pull-up transistor 360 and an activation transistor 370.

In the main word line control unit 210, a boost voltage VPP may be used as a pull-up voltage, and a negative voltage VBBW may be used as a pull-down voltage. The boost voltage VPP and the negative voltage VBBW may be generated inside a memory device.

The level of the boost voltage VPP may be higher than that of a power source voltage VDD, and the level of the negative voltage VBBW may be lower than that of a ground voltage VSS. The boost voltage VPP and the negative voltage VBBW are used to increase the swing width of a word line WL, and it is obvious that the pull-up voltage and the pull-down voltage used in the main word line control unit 210 are not limited to the boost voltage VPP and the negative voltage VBBW.

The activation transistor 370 may activate or deactivate the main word line control unit 210. The activation transistor 370 is turned on and off in response to a decoder activation signal XDECEN, and the main word line control unit 210 is activated while the activation transistor 370 is turned on.

The multiple first pull-down transistors 311 to 313 may be coupled in series with each other, and may pull down a control node A in response to the plurality of first address information signals BAX345<0:7>, BAX678<0:7> and BAX9AB<0:7>. Each of the first pull-down transistors 311, 312, 313 may receive one of the eight signals BAX345<0:7>, BAX678<0:7>, BAX9AB<0:7> (respectively). The total number of combinations is 512 (512=8*8*8) which is equal to the number of the main word line control units 210. That is, each of the main word line control units 210 may receive different combinations of the first address information signals BAX345<0:7>, BAX678<0:7> and BAX9AB<0:7>. When the multiple first pull-down transistors 311 to 313 are turned on, the control node A is driven at a logic ‘low’ level, which may activate a main word line driving signal MWLB<i>. Herein, <i> is an integer value ranging from 0 to 511.

The signals BAX345<0:7> of the first address information signals BAX345<0:7>, BAX678<0:7> and BAX9AB<0:7> may be generated by decoding third to fifth addresses, and just one of the signals BAX345<0:7> may have a value of ‘1’ and the others may have a value of ‘0’ according to the logic values of the third to fifth addresses. The signals BAX678<0:7> may be generated by decoding sixth to eighth addresses, and just one of the signals BAX678<0:7> may have a value of ‘1’ and the others may have a value of ‘0’ according to the logic values of the sixth to eighth addresses. The signals BAX9AB<0:7> may be generated by decoding ninth to eleventh addresses, and just one of the signals BAX9AB<0:7> may have a value of ‘1’ and the others may have a value of ‘0’ according to the logic values of the ninth to eleventh addresses. One of the main word line units 210 where all the first pull-down transistors 311 to 313 are turned on, namely three pull-down transistors 311 to 313, may receive the signal ‘1’. Therefore, one of the main word line units 210 may exist where the control node A is driven at logic ‘low’ level and the main word line driving signal MWLB<i> is activated.

The driving signal output unit 320 may activate the main word line driving signal MWLB<i> at a logic ‘low’ level when the control node A is activated at a ‘low’ level, and may deactivate the main word line driving signal MWLB<i> at a logic ‘high’ level when a word line off signal WLOFF is activated at a ‘high’ level. The driving signal output unit 320 may include a second pull-up transistor 321, an inverter 322, a second pull-down transistor 323 and a third pull-down transistor 324. When the control node A is activated at a logic ‘low’ level, the second pull-up transistor 321 is turned on and a preliminary driving signal B is at a logic ‘high’ level. Further, the preliminary driving signal B is inverted by the inverter 322 and the main word line driving signal MWLB<i> is activated at the logic ‘low’ level. When the word line off signal WLOFF is activated at a logic ‘high’ level, the third pull-down transistor 324 is turned on and the preliminary driving signal B is at a logic ‘low’ level. Further, the preliminary driving signal B is inverted by the inverter 322 and the main word line driving signal MWLB<i> is deactivated at a logic ‘high’ level. When the main word line driving signal MWLB<i> is deactivated at a logic ‘high’ level, the second pull-down transistor 323 is turned on, and the main word line driving signal MWLB<i> maintains its deactivation state.

The first pull-up transistor 330 may be turned on and may drive the control node A at a logic ‘high’ level while the preliminary driving signal B is at a logic ‘low’ level, or the main word line driving signal MWLB<i> is deactivated at a logic ‘high’ level.

The clamping unit 340 may limit the amount of current flowing to the first pull-up transistor 330. The clamping unit 340 may be a PMOS transistor, which receives a ground voltage VSS. Various clamping unit 340 designs, which are capable of limiting the amount of current flowing to the first pull-up transistor 330, will suffice. The reason why the clamping unit 340 is used is as follows. The control node A should be driven at the logic ‘low’ level so that the main word line driving signal MWLB<i> is activated at the logic ‘low’ level. The pull-down driving power of the multiple first transistors 311 to 313 should be stronger than the pull-up driving power of the first pull-up transistor 330 in order to drive the control node A at a logic ‘low’ level. As the number of the word lines increases, the number of first transistors 311 to 313 coupled in series with each other increases as well, which weakens the driving power of the multiple first transistors 311 to 313. Therefore, it needs to weaken the driving power of the first pull-up transistor 330 as well. For this reason, a clamping unit 340 is required. In other words, even though the number of the pull-down transistors 311 to 313 coupled in series with each other increases, the balanced driving power between the first pull-up transistor 330 and the first pull-down transistors 311 to 313 may be maintained by the clamping unit 340.

The third pull-up transistor 350 and the fourth pull-up transistor 360 may deactivate the main word line driving signal MWLB<i> in response to the activation of the word line off signal WLOFF. When the word line off signal WLOFF is activated, the third pull-up transistor 350 may drive the control node A at a logic ‘high’ level and the fourth pull-up transistor 360 may drive at least one of connection nodes between the first pull-down transistors 311 to 313 at a logic ‘high’ level.

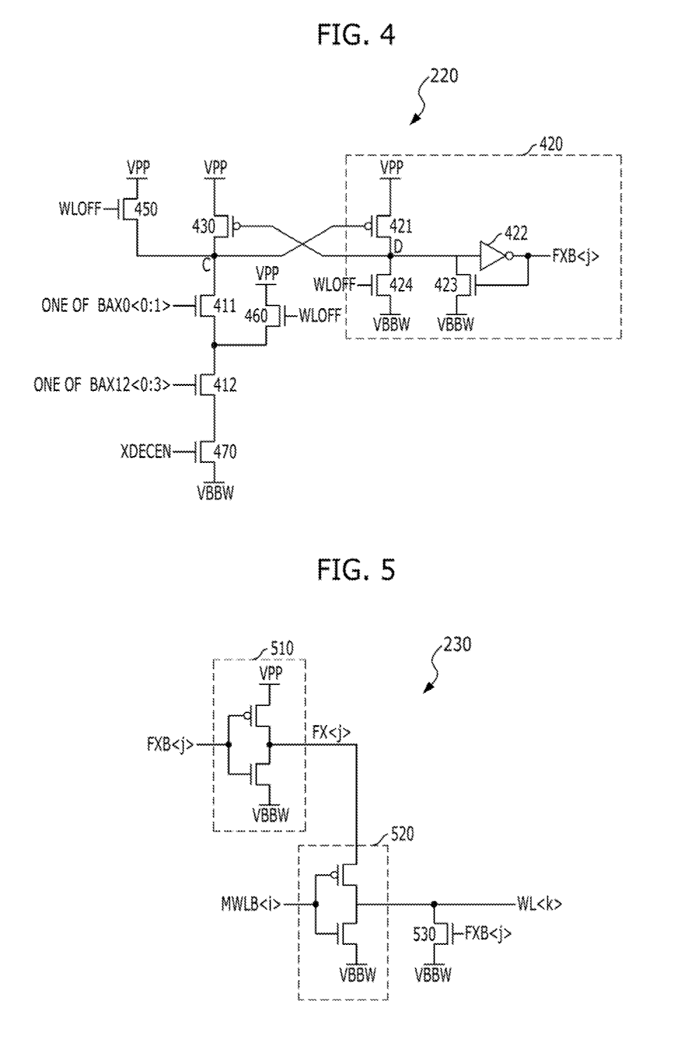

FIG. 4 is a block diagram illustrating an example of the local word line control unit 220 shown in FIG. 2. As described above, the local word line control unit 220 may equal the number of local word line driving signals FXB<0:7>. One of the local word line control units 220 is described in detail with reference to the accompanying drawing FIG. 4.

Referring to FIG. 4, the local word line control unit 220 may include a plurality of third pull-down transistors 411 to 412, a driving signal output unit 420, a fifth pull-up transistor 430, a seventh pull-up transistor 450, an eighth pull-up transistor 460 and an activation transistor 470.

The signals BAX0<0:1> of the second address information signals BAX0<0:1> and BAX12<0:3> may be generated by decoding a 0^{th} address, and one of two signals BAX0<0:1> may have a value of ‘1’ according to the logic value of the 0^{th} address. The signals BAX12<0:3> may be generated by decoding first and second addresses, just one of the signals BAX12<0:3> may have a value of ‘1’ and the others may have a value of ‘0’ according to the logic values of the first and second addresses.

The third pull-down transistors 411 to 412 of the local word line control unit 220 may be similar to the first pull-down transistors 311 to 313 of the main word line control unit 210. Similarly, the driving signal output unit 420, the fifth pull-up transistor 430, the seventh pull-up transistor 450, the eighth pull-up transistor 460 and the activation transistor 470 of the local word line control unit 220 may correspond to the driving signal output unit 320, the first pull-up transistor 330, the third pull-up transistor 350, the fourth pull-up transistor 360 and the activation transistor 370 of the main word line control unit 210, respectively.

There are several differences between the local word line control unit 220 and the main word line control unit 210. The number of the third pull-down transistors 411 to 412 may be smaller than the number of the first pull-down transistors 311 to 313 since the number of the local word line control signals FXB<0:7> may be smaller than the number of the main word line control signals MWLB<0:511>. Also, the clamping unit 340 may not be used for the local word line control unit 220 since the number of the third pull-down transistors 411 to 412 coupled in series with each other may not be as great as the number of the first pull-down transistors 311 to 313, and thus the third pull-down transistors 411 to 412 may have enough pull-down driving power. Also, when the number of the local word line control units 220 is smaller than the number of main word line control units 210, the need for the clamping unit 340 in the local word line control unit 220 may decrease accordingly, and thus it may be easier to design the third pull-down transistors 411 to 412 in a size large enough for pull-down driving power. Of course, the local word line control unit 220 may be designed to include the clamping unit 340.

When the local word line driving signal FXB<j> (where <j> is an integer value ranging from 0 to 7) is driven by the second address information signals BAX0<0:1> and BAX12<0:3>, the local word line control unit 220 may activate the local word line driving signal FXB<j> at the logic ‘low’ level and may deactivate the local word line driving signals FXB<j> at the logic ‘high’ level in response to the activation of the word line off signal WLOFF. The number of signals which are selected according to the second address information signals BAX0<0:1> and BAX12<0:3> of the local word line driving signals FXB<0:7> and activated is just one. For reference, the local word line driving signal FXB<0:7> may be referred to as a phi X driving signal.

FIG. 5 is a block diagram illustrating an example of a word line driver 230 shown in FIG. 2. As described above, as many word line drivers 230 may be provided to equal the number of the word lines WL<0:4095>. One of the word line drivers 230 is described in detail with reference to the accompanying drawing FIG. 5.

Referring to FIG. 5, the word line driver 230 may include two inverters 510 and 520 and a transistor 530.

The inverter 510 may invert the local word line driving signal FXB<j>. When the local word line driving signal FXB<j> is activated at a logic ‘low’ level, the output signal FX<j> of the inverter 510 may have a logic level of the pull-up voltage VPP. When the local word line driving signal FXB<j> is deactivated at the logic ‘high’ level, the output signal FX<j> of the inverter 510 may have a logic level of the pull-down voltage VBBW.

The inverter 520 may receive the main word line driving signal MWLB<i>. When the main word line driving signal MWLB<i> is activated at a logic ‘low’ level, the output signal FX<j> of the inverter 510 may be driven as a word line WL<k> (where <k> is an integer value ranging from 0 to 4095). As a result, when both the main word line driving signal MWLB<i> and the local word line driving signal FXB<j> are activated at the logic ‘low’ level, the word line WL<k> may be activated at the logic ‘high’ level. When the main word line driving signal MWLB<i> is deactivated at the logic ‘high’ level, the word line WL<k> may be deactivated at the logic ‘low’ level by the inverter 520.

The transistor 530 may drive the word line WL<k> at the logic ‘low’ level when the local word line driving signal FXB<j> is deactivated at the logic ‘high’ level.

The word line WL<k> may be referred to as a sub-word line in order to distinguish it from the main word line driving signal MWLB<i>.

As described above, in accordance with the embodiments of the present invention, a word line driving circuit for driving a plurality of word lines may be performed with reduced failure.

While the present invention has been described with respect to specific embodiments, it should be noted that the embodiments are for describing, not limiting, the present invention. Further, it should be noted that the present invention may be achieved in various ways through substitution, change, and modification, by those skilled in the art without departing from the scope of the present invention as defined by the following claims.

What is claimed is:

1. A word line driving circuit comprising:
a plurality of first pull-down transistors connected in series, and suitable for pull-down driving a control node in response to a plurality of address information signals;
a driving signal output unit suitable for activating a word line driving signal when the control node is activated, and deactivating the word line driving signal when a word line off signal is activated;
a first pull-up transistor suitable for pull-up driving the control node when the word line driving signal is deactivated; and
a clamping unit suitable for limiting the amount of current flowing to the first pull-up transistor.

2. The word line driving circuit of claim 1, wherein the driving signal output unit comprises:
a second pull-up transistor suitable for pull-up driving a preliminary driving signal in response to the control node;
an inverter suitable for generating the word line driving signal in response to the preliminary driving signal;
a second pull-down transistor suitable for pull-down driving the preliminary driving signal in response to the word line driving signal; and
a third pull-down transistor suitable for pull-down driving the preliminary driving signal in response to the word line off signal.

3. The word line driving circuit of claim 1, further comprising:
a third pull-up transistor suitable for pull-up driving the control node in response to the word line off signal.

4. The word line driving circuit of claim 3, further comprising:
a fourth pull-up transistor suitable for pull-up driving at least one of connection nodes of the plurality of first pull-down transistors in response to the word line off signal.

5. The word line driving circuit of claim 1, wherein all of the plurality of first pull-down transistors are turned on and pull down the control node in response to the plurality of address information signals, which are set to activate the word line driving signal.

6. The word line driving circuit of claim 1, wherein the word line driving signal is a main word line driving signal.

7. The word line driving circuit of claim 1, wherein the word line driving signal is a local word line driving signal.

8. A word line driving circuit, comprising:
a plurality of main word line control units suitable for generating a plurality of main word line driving signals in response to a plurality of first address information signals;
a plurality of local word line control units suitable for generating a plurality of local word line driving signals in response to a plurality of second address information signals; and
a plurality of word line drivers suitable for driving a plurality of word lines according to the multiple main word line driving signals and local word line driving signals,
wherein each of the multiple main word line control units comprises:
a plurality of first pull-down transistors connected in series and suitable for pull-down driving a first control node in response to the plurality of first address information signals;
a driving signal output unit suitable for activating a main word line driving signal when the first control node is activated, and deactivating the main word line driving signal when a word line off signal is activated;
a first pull-up transistor suitable for pull up driving the first control node when the main word line driving signal is deactivated; and
a clamping unit suitable for limiting the amount of current flowing to the first pull-up transistor.

9. The word line driving circuit of claim 8, wherein the driving signal output unit comprises:
a second pull-up transistor suitable for pull-up driving a preliminary driving signal in response to the first control node;
an inverter suitable for generating the main word line driving signal in response to the preliminary driving signal;
a second pull-down transistor suitable for pull-down driving the preliminary driving signal in response to the main word line driving signal; and
a third pull-down transistor suitable for pull-down driving the preliminary driving signal in response to the word line off signal.

10. The word line driving circuit of claim 8, wherein each of the main word line control units further includes a third pull-up transistor suitable for pull-up driving the first control node in response to the word line off signal.

11. The word line driving circuit of claim 10, wherein each of the main word line control units further includes a fourth pull-up transistor for pull-up driving at least one of connection nodes of the plurality of first pull-down transistors in response to the word line off signal.

12. The word line driving circuit of claim 8, wherein a word line among the plurality of word lines, which is selected according to the plurality of first address information signals and the plurality of second address information signals, is activated.

13. The word line driving circuit of claim 8, wherein each of the plurality local word line control units comprises:
a plurality of third pull-down transistors connected in series, and suitable for pull-down driving a second contact node in response to the plurality of second address information signals;
a driving signal output unit suitable for activating a local word line driving signal when the second control node is activated, and deactivating the local word line driving signal when the word line off signal is activated; and
a fifth pull-up transistor suitable for pull-up driving the second control node when the main word line driving signal is deactivated.

14. The word line driving circuit of claim 13, wherein each of the multiple local word line control units further includes a clamping unit suitable for limiting the amount of current flowing to the fifth pull-up transistor.
